(19) United States
(12) Patent Application Publication
(10) Pub. No.: US 2026/0061738 A1
(43) Pub. Date: Mar. 5, 2026

(54) MASK ASSEMBLY

(71) Applicant: Samsung Display Co., LTD., Yongin-si (KR)

(72) Inventors: Min Ji JANG, Yongin-si (KR); Hong Kyun AHN, Yongin-si (KR); Dong Jin HA, Yongin-si (KR)

(21) Appl. No.: 19/220,937

(22) Filed: May 28, 2025

(30) Foreign Application Priority Data
Sep. 5, 2024 (KR) 10-2024-0120631

(51) Int. Cl. B41F 15/36; B41F 15/08; H10K 71/16

(52) U.S. Cl. CPC B41F 15/36; B41F 15/0813; H10K 71/166

(57) ABSTRACT

A mask assembly includes a frame in which an opening is defined, a mask stick disposed on the frame and in which a plurality of pattern openings are defined, and a mask member disposed on the frame and including a plurality of supporting parts covering at least a portion of the pattern openings to form a deposition area, where at least one supporting part among the plurality of supporting parts is wider in width or thicker in thickness than other supporting parts.

This application claims priority to Korean Patent Application No. 10-2024-0120631, filed on Sep. 5, 2024, and all the benefits accruing therefrom under 35 U.S.C. 119, the content of which in its entirety is herein incorporated by reference.

### BACKGROUND

### 1. Technical Field

The present disclosure relates to a mask assembly.

### 2. Description of the Related Art

Flat panel display devices such as a liquid crystal display (LCD) and an organic light-emitting diode (OLED) display are widely being used. A flat panel display device includes a metal layer having a predetermined pattern, and an OLED display forms an organic light-emitting layer having a predetermined pattern in each pixel. The metal layer and the organic light-emitting layer may be formed by a deposition method using a mask assembly.

The mask assembly includes a mask stick in which pattern openings are formed to correspond to the pattern of the metal layer or the organic light-emitting layer and a mask frame which supports the mask stick. The mask stick is provided in plural numbers, and the plurality of mask sticks may be consecutively disposed on the top portion of the mask frame. Each mask stick may be fixed to the mask frame by welding.

A separate mask member for differentiating a deposition area may be disposed between the mask stick and the mask frame.

### SUMMARY

Aspects of the present disclosure provide a mask assembly capable of stably depositing a deposition material on a substrate by minimizing change of a mask member.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a mask assembly includes a frame in which an opening is defined, a mask stick disposed on the frame and in which a plurality of pattern openings are defined, and a mask member disposed on the frame and including a plurality of supporting parts covering at least a portion of the pattern openings to form a deposition area, where at least one supporting part among the plurality of supporting parts is wider in width or thicker in thickness than other supporting parts.

The mask member may further include an edge part forming a mask opening therein, and the plurality of supporting parts may include a first main supporting part extending in a first direction from the edge part to cross the mask opening, a second main supporting part extending in the first direction from the edge part to cross the mask opening and spaced apart from the first main supporting part, and at least one auxiliary supporting part extending in a second direction crossing the first direction from the second main supporting part to the edge part.

A width of the second main supporting part in the second direction may be wider than a width of each of the at least one the auxiliary supporting part in the first direction.

A width of the second main supporting part in the second direction may be wider than a width of the first main supporting part in the second direction.

A thickness of the second main supporting part may be thicker than a thickness of the auxiliary supporting part.

A thickness of the second main supporting part may be thicker than a thickness of the first main supporting part.

The second main supporting part may include a first part and a main reinforcing part disposed on the first part, where the plurality of supporting parts may further includes an auxiliary reinforcing part disposed on the auxiliary supporting part.

A total thickness of the auxiliary supporting part and the auxiliary reinforcing part may be the same as a thickness of the second main supporting part.

The auxiliary reinforcing part may extend from the main reinforcing part in the second direction.

A length of the auxiliary reinforcing part in the second direction may be shorter than a length of the auxiliary supporting part in the second direction.

A width of the auxiliary reinforcing part in the first direction may be the same as a width of the auxiliary supporting part in the first direction.

The auxiliary supporting part may be provided in plural numbers, the plurality of auxiliary supporting parts may include a first auxiliary supporting part and a second auxiliary supporting part, the auxiliary reinforcing part is provided in plural numbers, the plurality of auxiliary reinforcing parts includes a first auxiliary reinforcing part and a second auxiliary reinforcing part, the first auxiliary reinforcing part is disposed on the first auxiliary supporting part, and the second auxiliary reinforcing part is disposed on the second auxiliary supporting part.

Each of the first auxiliary reinforcing part and the second auxiliary reinforcing part may be extended from the main reinforcing part in the second direction, but the cross-sectional area of each of the first auxiliary reinforcing part and the second auxiliary reinforcing part in the first direction may gradually decrease in the second direction.

The first auxiliary reinforcing part may include a first inclined surface, the first inclined surface may be extended in a direction between the first direction and the second direction, the second auxiliary reinforcing part may include a second inclined surface, and the second inclined surface is extended in a direction between the second direction and a direction opposite to the first direction.

The first auxiliary reinforcing part and the second auxiliary reinforcing part may be extended from the main reinforcing part to the outer end of the edge part in the second direction.

The width of the first auxiliary reinforcing part in the first direction may be smaller than the width of the first auxiliary supporting part in the first direction, and the width of the second auxiliary reinforcing part in the first direction may be smaller than the width of the second auxiliary supporting part in the first direction.

The first auxiliary reinforcing part may be disposed at the side closer to the edge part among opposite sides of the first auxiliary supporting part in the second direction, and the second auxiliary reinforcing part may be disposed at the side closer to the edge part among opposite sides of the second auxiliary supporting part in the second direction.

The plurality of supporting parts may further include a third main supporting part extended from the edge part in the second direction to be connected to the first main supporting part and the second main supporting part.

The mask stick may be provided in plural numbers, and the plurality of mask sticks may be consecutively arranged on the frame to cover the opening of the frame.

At least one mask stick among the plurality of mask sticks may have a wider width than the other mask sticks in the second direction.

According to an aspect of the present disclosure, an electronic device includes a display device manufactured by a mask assembly, a mask assembly includes a frame in which an opening is formed, a mask stick disposed on the frame and in which a plurality of pattern openings are formed, and a mask member disposed on the frame and including a plurality of supporting parts covering at least a portion of the pattern openings to form a deposition area, where at least one supporting part among the plurality of supporting parts is wider in width or thicker in thickness than the other supporting part.

According to the mask assembly of the present disclosure, there is an effect of stably depositing a deposition material on a substrate by minimizing change of a mask member by widening the width or thickening the thickness of at least one supporting part among a plurality of supporting parts of a mask member.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view of a mask assembly according to one embodiment of the present disclosure;

FIG. 2 is a side view of FIG. 1;

FIG. 3 is a plan view of a frame of FIG. 1;

FIG. 4 is a plan view of a mask stick of FIG. 1;

FIG. 5 is a plan view of a first mask stick of FIG. 4;

FIG. 6 is a plan view of a second mask stick of FIG. 4;

FIG. 7 is a plan view illustrating a first embodiment of a mask frame in a mask assembly according to one embodiment of the present disclosure;

FIG. 8 is a plan view illustrating a second main supporting part, a main reinforcing part, a first auxiliary supporting part, a first auxiliary reinforcing part, a second auxiliary supporting part, and a second auxiliary reinforcing part of FIG. 7;

FIG. 9 is a cross-sectional view taken along line A-A′ of FIG. 7;

FIG. 10 is a plan view illustrating a second embodiment of a mask member in a mask assembly according to one embodiment of the present disclosure;

FIG. 11 is a plan view illustrating a second main supporting part, a main reinforcing part, a first auxiliary supporting part, a first auxiliary reinforcing part, a second auxiliary supporting part, and a second auxiliary reinforcing part of FIG. 10;

FIG. 12 is a cross-sectional view taken along line B-B′ of FIG. 10;

FIG. 13 is a plan view illustrating a third embodiment of a mask member in a mask assembly according to one embodiment of the present disclosure;

FIG. 14 is a plan view illustrating a second main supporting part, a main reinforcing part, a first auxiliary supporting part, a first auxiliary reinforcing part, a second auxiliary supporting part, and a second auxiliary reinforcing part of FIG. 13; and

FIG. 15 is a cross-sectional view taken along line C-C′ of FIG. 13.

FIG. 16 is a block diagram of an electronic device according to one embodiment of the present disclosure.

FIG. 17 is a schematic diagram of an electronic device according to various embodiments of the present disclosure.

### DETAILED DESCRIPTION

Advantages and features of the present disclosure and methods to achieve them will become apparent from the descriptions of example embodiments hereinbelow with reference to the accompanying drawings. However, the present disclosure is not limited to example embodiments disclosed herein but may be implemented in various different ways. The example embodiments are provided for making the disclosure of the present disclosure thorough and for fully conveying the scope of the present disclosure to those skilled in the art. It is to be noted that the scope of the present disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Although terms such as “first”, “second”, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various example embodiments of the present disclosure may be combined partially or totally. As will be clearly appreciated by those skilled in the art, technically various interactions and operations are possible. Various example embodiments can be practiced individually or in combination.

Hereinafter, example embodiments of the present disclosure will be described in detail with reference to the accompanying drawings.

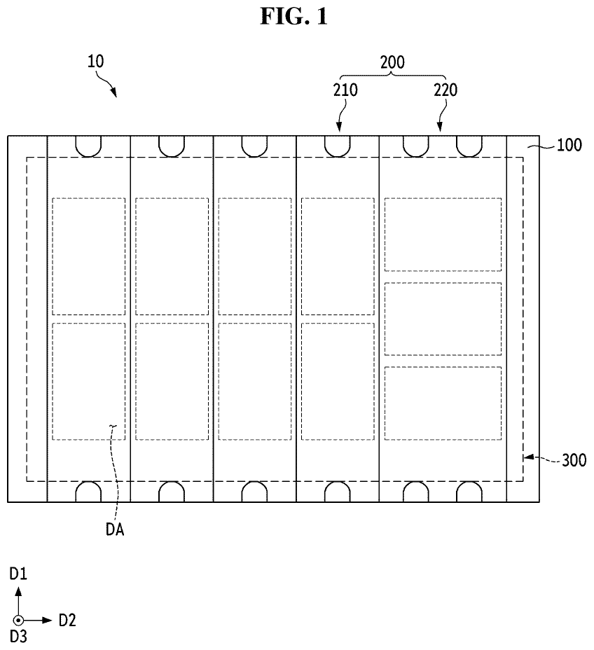

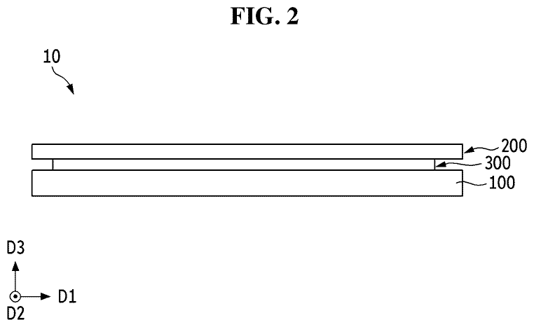

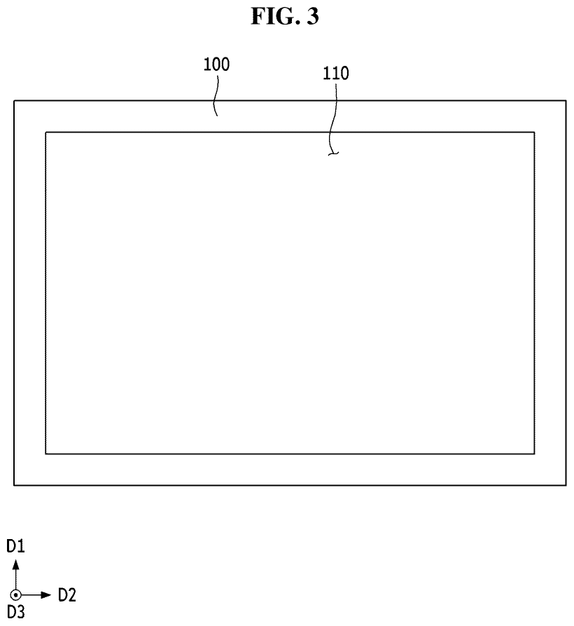

FIG. 1 is a plan view of a mask assembly according to one embodiment of the present disclosure. FIG. 2 is a side view of FIG. 1. FIG. 3 is a plan view of a frame of FIG. 1. As used herein, the “plan view” is a view in a thickness direction (third direction DR3) of the mask assembly 10.

Referring to FIGS. 1 to 3, a mask assembly 10 according to one embodiment of the present disclosure may include a frame 100, a mask stick 200, and a mask member 300.

The frame 100 forms an outer frame of the mask assembly 10, and may have a square strip shape with an opening 110 defined in the center. The frame 100 may have a predetermined thickness in the third direction (i.e., third direction D3) to stably support the mask stick 200 and the like. The frame 100 may include a pair of short sides and a pair of long sides, and the opening 110 may be defined in the center of the frame 100. For example, the one pair of short sides may be extended in a first direction D1 to be disposed parallel in a second direction D2, and the one pair of long sides may be extended in the second direction D2 to be disposed parallel in the first direction D1.

In one embodiment, the planar shape of the opening 110 may be approximately rectangular. The opening 110 may provide a path through which a deposition material passes. In another embodiment, the frame 100 may have a square strip shape with two sides of the same length, and the planar shape of the opening 110 may be quadrilateral. The frame 100 may include a material with strong rigidity, for example, a metal such as stainless steel. As used herein, the “planar shape” of an object is a shape of the object in a plan view.

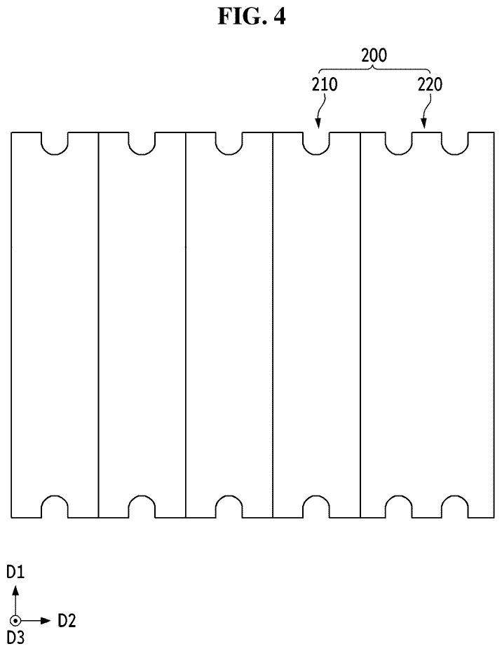

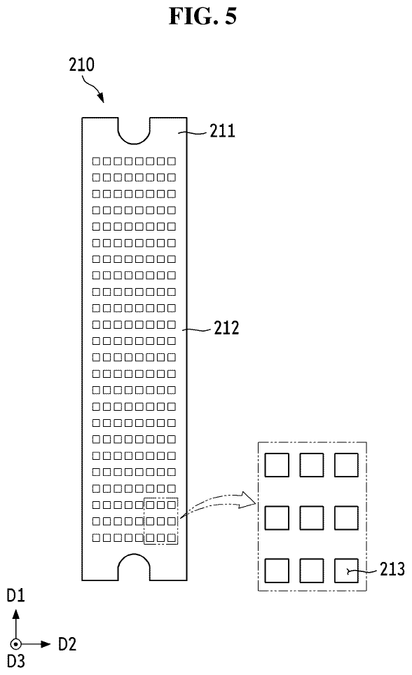

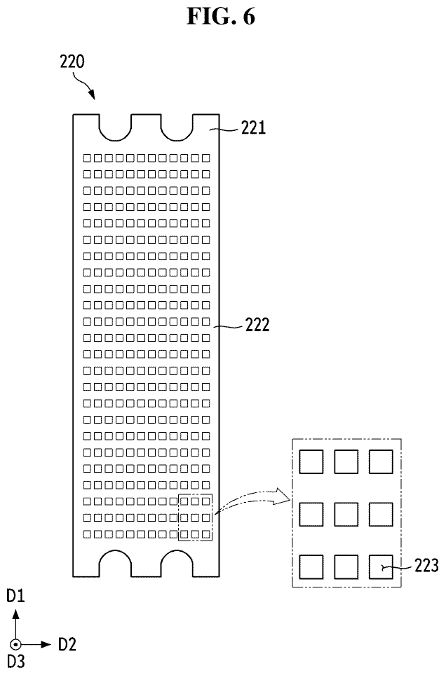

FIG. 4 is a plan view of a mask stick of FIG. 1. FIG. 5 is a plan view of a first mask stick of FIG. 4. FIG. 6 is a plan view of a second mask stick of FIG. 4.

Referring to FIGS. 4 to 6 further, the mask stick 200 may be disposed on the frame 100. The mask stick 200 may be provided in plural numbers, and the plurality of mask sticks 200 may be consecutively disposed to cover the opening 110 of the frame 100. The plurality of mask sticks 200 may include a first mask stick 210 and a second mask stick 220.

The first mask stick 210 may have one surface (top surface of FIG. 2) and the other surface (bottom surface of FIG. 2). The other surface of the first mask stick 210 may be a surface to face a substrate (not illustrated) in a deposition process, and the one surface of the first mask stick 210 may be the opposite surface of the other surface of the first mask stick 210 and where the deposition material is provided. The other surface of the first mask stick 210 may be in contact with the mask member 300.

The length (e.g., length in the first direction D1) of the first mask stick 210 may be larger than the width (e.g., width in the second direction D2) thereof. In one embodiment, the first mask stick 210 may be extended in the first direction D1. The width of the first mask stick 210 may be smaller than the width of the second mask stick 220. The first mask stick 210 may be provided in plural numbers, and may be disposed consecutively in the second direction D2. In another embodiment, the first mask stick 210 may be a raw mask integrally formed with a planar area covering the opening 110. In this case, the first mask stick 210 and the second mask stick 220 may be provided as one raw mask without distinction.

The first mask stick 210 may be a fine metal mask formed of a metal material. The first mask stick 210 may be formed of a metal such as stainless steel, Ni, cobalt (Co), or an alloy thereof. In some embodiments, the first mask stick 210 may exhibit magnetic properties.

The first mask stick 210 may include a first fixing part 211 positioned at opposite ends in the first direction D1 and a first body 212 positioned at the center compared to the first fixing part 211.

The first fixing part 211 may be a portion where the frame 100 comes into contact and is combined. For example, the first fixing part 211 may be welded and combined with the frame 100. The method by which the first fixing part 211 is welded to the frame 100 is not particularly limited, but laser welding, resistance heat welding and the like may be exemplified.

The first body 212 may be a portion in which a plurality of first pattern openings 213 providing a path through which the deposition material passes are formed. The first body 212 may be disposed between both sides of the first fixing part 211. The first pattern opening 213 may be an opening penetrating the one surface and the other surface of the first mask stick 210. The first pattern openings 213 of the first mask stick 210 aligned on the substrate may expose a deposition area DA of the substrate. In some embodiments, the first pattern opening 213 may have substantially the same planar shape as a deposition pattern. In the present embodiment, it is exemplified that first pattern openings 213 are spaced apart in first and second directions D1 and D2 and aligned in approximately a matrix shape with dot shape in a plan view, but the present disclosure is not limited thereto, and the first pattern opening 213 may have a slit shape extending in the first direction D1 or the second direction D2 in a plan view.

The first mask stick 210 may be fixed to the frame 100 by welding while tension is applied to opposite ends in the first direction D1 or the second direction D2. In another embodiment, the first mask stick 210 may be stretched not only in the first direction D1 but also in the second direction D2.

The second mask stick 220 may have one surface (top surface of FIG. 2) and the other surface (bottom surface of FIG. 2). The other surface of the second mask stick 220 may be a surface facing the substrate (not illustrated) in a deposition process, and the one surface of the second mask stick 220 may be the opposite surface of the other surface of the second mask stick 220 and where the deposition material is provided. The other surface of the second mask stick 220 be in contact with the mask member 300.

The length (e.g., length in the first direction D1) of the second mask stick 220 may be larger than the width (e.g., width in the second direction D2) thereof. In one embodiment, the second mask stick 220 may be extended in the first direction D1. The width of the second mask stick 220 may be wider than the width of the first mask stick 210 in the second direction D2. The second mask stick 220 may be consecutively disposed with the first mask stick 210. In another embodiment, the second mask stick 220 may be a raw mask integrally formed with a planar area covering the opening 110. In this case, the first mask stick 210 and the second mask stick 220 may be provided as one raw mask without distinction.

The second mask stick 220 may be a fine metal mask formed of a metal material. The second mask stick 220 may be formed of a metal such as stainless steel, Ni, cobalt (Co), or an alloy thereof. In some embodiments, the second mask stick 220 may exhibit magnetic properties.

The second mask stick 220 may include a second fixing part 221 positioned at opposite ends in the first direction D1 and a second body 222 positioned at the center of second mask stick 220.

The second fixing part 221 may be a portion where the frame 100 comes into contact and is combined. For example, the second fixing part 221 may be welded and combined with the frame 100. The method by which the second fixing part 221 is welded to the frame 100 is not particularly limited, but laser welding, resistance heat welding and the like may be exemplified.

The second body 222 may be a portion in which a plurality of second pattern openings 223 providing a path through which the deposition material passes are defined. The second body 222 may be disposed between the opposite sides of the second fixing part 221 in the first direction D1. The second pattern opening 223 may be an opening penetrating the one surface and the other surface of the second mask stick 220. The second pattern openings 223 of the second mask stick 220 aligned on the substrate may expose the deposition area DA of the substrate. In some embodiments, the second pattern opening 223 may have substantially the same planar shape as the deposition pattern. In the present embodiment, it is exemplified that second pattern opening 223 are spaced apart in first and second directions D1 and D2 and aligned in approximately matrix shape with dot shape in a plan view, but the present disclosure is not limited thereto, and the second pattern opening 223 may have a slit shape extending in the first direction D1 or the second direction D2 in a plan view in another embodiment.

The second mask stick 220 may be fixed to the frame 100 by welding while tension is applied to opposite ends in the first direction D1 or the second direction D2. In another embodiment, the second mask stick 220 may be stretched not only in the first direction D1 but also in the second direction D2.

Hereinafter, referring to the drawing, various embodiments of the mask member 300, which is a key feature of the mask assembly 10 according to one embodiment of the present disclosure, will be described below.

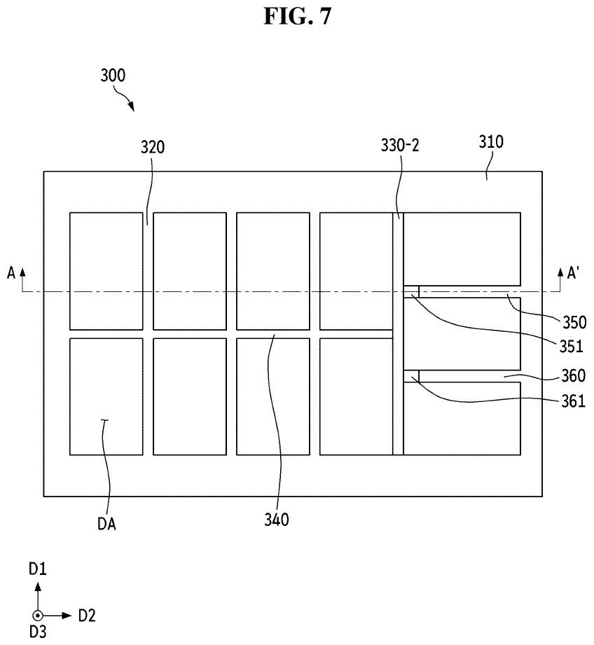

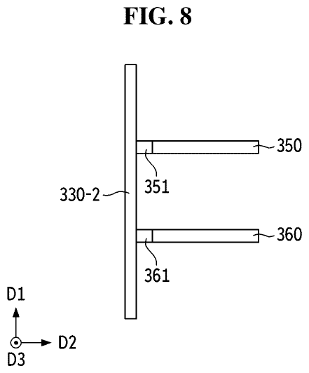

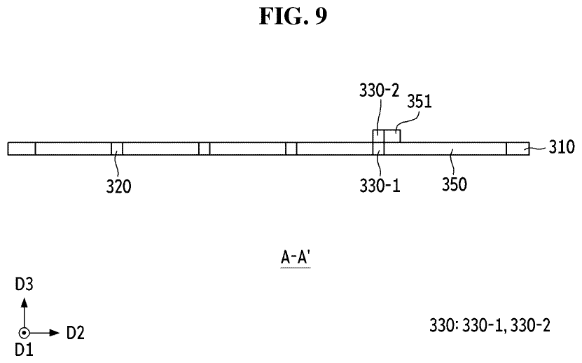

FIG. 7 is a plan view illustrating a first embodiment of a mask frame in a mask assembly according to one embodiment of the present disclosure. FIG. 8 is a plan view illustrating a second main supporting part, a main reinforcing part, a first auxiliary supporting part, a first auxiliary reinforcing part, a second auxiliary supporting part, and a second auxiliary reinforcing part of FIG. 7. FIG. 9 is a cross-sectional view taken along line A-A′ of FIG. 7.

Referring to FIGS. 7 to 9, a mask member 300 according to the first embodiment may be disposed on the frame 100 and cover at least a portion of the first pattern openings 213 and the second pattern openings 223 to form the deposition area DA. The deposition area DA may correspond to one display device (e.g., an organic light emitting display device). In this case, patterns corresponding to a plurality of display devices may be simultaneously deposited by a single process using one mask assembly 10. In some embodiments, the mask assembly 10 may correspond to one raw substrate (a mother substrate) and may form patterns corresponding to a plurality of display devices on the raw substrate.

The mask member 300 may include an edge part 310, a first main supporting part 320, a second main supporting part 330, 330-2a third main supporting part 340, a first auxiliary supporting part 350, a first auxiliary reinforcing part 351, a second auxiliary supporting part 360, and a second auxiliary reinforcing part 361. The second main supporting part 330 may include a first part 330-1 and a second part 330-2 (hereinafter, “main reinforcing part”).

The edge part 310 forms an outer frame of the mask member 300, and may have a square strip shape with a mask opening defined in the center therein. The edge part 310 may include a pair of short sides and a pair of long sides, and the mask opening may be defined in the center therein. For example, the one pair of short sides may be extended in a first direction D1 to be disposed parallel in a second direction D2, and the one pair of long sides may be extended in the second direction D2 to be disposed parallel in the first direction D1. The length of the short side of the edge part 310 may be shorter than the length of the short side of the frame 100, and the length of the long side of the edge part 310 may be shorter than the length of the long side of the frame 100.

In one embodiment, the planar shape of the mask opening may be approximately rectangular. The mask opening may provide a path through which a deposition material passes. The mask opening may be divided by a plurality of supporting parts to form the deposition area DA.

The first main supporting part 320 may extend from the edge part 310 in the first direction D1 to cross the mask opening. In some embodiments, the first main supporting part 320 may extend in the first direction D1 from the lower side of the edge part 310 of FIG. 7 to the upper side of the edge part 310 of FIG. 7. The first main supporting part 320 may be provided in plural numbers and be disposed to be spaced apart in the second direction D2. The thickness of the first main supporting part 320 may correspond to the thickness of the edge part 310. As used herein, the thickness is measured in the thickness direction (third direction DR3).

The first part 330-1 may extend from the edge part 310 in the first direction D1 to cross the mask opening. In some embodiments, the first part 330-1 may extend in the first direction D1 from the lower side of the edge part 310 of FIG. 7 to the upper side of the edge part 310 of FIG. 7. The first part 330-1 may be disposed to be spaced apart from the first main supporting part 320 in the second direction D2.

The width of the first part 330-1 (width in the second direction D2) may be wider than each of the width of the first main supporting part 320 (width in the second direction D2) and the width of the third main supporting part 340 (width in the first direction D1). In addition, the width of the first part 330-1 may be wider than each of the width of the first auxiliary supporting part 350 (width in the first direction D1) and the width of the second auxiliary supporting part 360 (width in the first direction D1). In some embodiments, the width of the first part 330-1 may be formed to be wider than each of the width of the first main supporting part 320, the width of the third main supporting part 340, the width of the first auxiliary supporting part 350, and the width of the second auxiliary supporting part 360 to have an even greater rigidity. Accordingly, the second main supporting part 330 may be effectively prevented from being easily deformed.

The thickness of the first part 330-1 may correspond to each of the thickness of the edge part 310, the thickness of the first main supporting part 320, the thickness of the third main supporting part 340, the thickness of the first auxiliary supporting part 350, and the thickness of the second auxiliary supporting part 360.

The main reinforcing part 330-2 may be disposed on the first part 330-1. The main reinforcing part 330-2 may have a length corresponding to the length of the first part 330-1 in the first direction D1 and a width corresponding to the width of the first part 330-1 in the second direction D2. As the main reinforcing part 330-2 is disposed on the upper portion of the first part 330-1, the thickness of the first part 330-1 including the main reinforcing part 330-2 may become thicker than each of the thickness of the edge part 310, the thickness of the first main supporting part 320, the thickness of the third main supporting part 340, the thickness of the first auxiliary supporting part 350, and the second auxiliary supporting part 360. The main reinforcing part 330-2 may be provided separately from the first part 330-1 to be disposed on the upper portion of the first part 330-1, or may be integrally formed with the first part 330-1.

The third main supporting part 340 may be extended from the edge part 310 to cross the mask opening in the second direction D2. In some embodiments, the third main supporting part 340 may be extended from the left side of FIG. 7 of the edge part 310 in the second direction D2 to be connected to a plurality of first main supporting parts 320 and the first part 330-1. Like described above, as the third main supporting part 340 is connected to the plurality of first main supporting parts 320 and the first part 330-1, a deposition area DA may be formed between the third main supporting part 340 and the plurality of first main supporting parts 320 and the first part 330-1. The thickness of the third main supporting part 340 may correspond to the thickness of the edge part 310.

The first auxiliary supporting part 350 may be extended from the first part 330-1 to cross the mask opening in the second direction D2. In some embodiments, the first auxiliary supporting part 350 may be extended from the first part 330-1 in the second direction D2 to be connected to the edge part 310. Like described above, as the first auxiliary supporting part 350 is connected to the first part 330-1 and the edge part 310, the deposition area DA may be formed between the first part 330-1, the first auxiliary supporting part 350, and the edge part 310. The thickness of the first auxiliary supporting part 350 may correspond to the thickness of the edge part 310. In addition, the thickness of the first auxiliary supporting part 350 may correspond to the thickness of the first part 330-1.

The first auxiliary reinforcing part 351 may be disposed on the first auxiliary supporting part 350. The first auxiliary reinforcing part 351 may be formed to have a width corresponding to the width of the first auxiliary supporting part 350 in the first direction D1 and a length shorter than the length of the first auxiliary supporting part 350 in the second direction D2. As the first auxiliary reinforcing part 351 is disposed on the upper portion of the first auxiliary supporting part 350, the total thickness of the first auxiliary supporting part 350 and the first auxiliary reinforcing part 351 near the first part 330-1 may be increased compared to a part of the first auxiliary supporting part 350 without the first auxiliary reinforcing part 351 thereon. As the total thickness of the first auxiliary supporting part 350 and the first auxiliary reinforcing part 351 near the first part 330-1 increases, the sum of the first auxiliary supporting part 350 and the first auxiliary reinforcing part 351 may have an even greater rigidity. Accordingly, the sum of the first auxiliary supporting part 350 and the first auxiliary reinforcing part 351 may be prevented from being easily deformed. The first auxiliary reinforcing part 351 may be provided separately from the first auxiliary supporting part 350 and placed on the upper part of the first auxiliary supporting part 350, or may be formed integrally with the first auxiliary supporting part 350. Additionally, the first auxiliary reinforcing part 351 may be formed integrally with the main reinforcing part 330-2.

The second auxiliary supporting part 360 may be extended from the first part 330-1 to cross the mask opening in the second direction D2. In some embodiments, the second auxiliary supporting part 360 may be extended from the first part 330-1 in the second direction D2 to be connected to the edge part 310. The second auxiliary supporting part 360 may be disposed to be spaced apart from the first auxiliary supporting part 350 in the first direction D1. Like described above, as the second auxiliary supporting part 360 is connected to the first part 330-1 and the edge part 310, the deposition area DA may be formed between the first part 330-1, the first auxiliary supporting part 350, the second auxiliary supporting part 360, and the edge part 310. The thickness of the second auxiliary supporting part 360 may correspond to the thickness of the edge part 310. Additionally, the thickness of the second auxiliary supporting part 360 may be the same or less than the thickness of the first part 330-1.

The second auxiliary reinforcing part 361 may be disposed on the second auxiliary supporting part 360. The second auxiliary reinforcing part 361 may be formed to have a width corresponding to the width of the second auxiliary supporting part 360 in the first direction D1 and a length shorter than the length of the second auxiliary supporting part 360 in the second direction D2. As the second auxiliary reinforcing part 361 is disposed on the upper part of the second auxiliary supporting part 360, the thickness of the second auxiliary supporting part 360 near the first part 330-1 may be increased. As the thickness of the second auxiliary supporting part 360 near the first part 330-1 increases, the second auxiliary supporting part 360 may have an even greater rigidity. Accordingly, the second auxiliary supporting part 360 may be prevented from being easily deformed. The second auxiliary reinforcing part 361 may be provided separately from the second auxiliary supporting part 360 and placed on the upper part of the second auxiliary supporting part 360, or may be formed integrally with the second auxiliary supporting part 360. Additionally, the second auxiliary reinforcing part 361 may be formed integrally with the main reinforcing part 330-2.

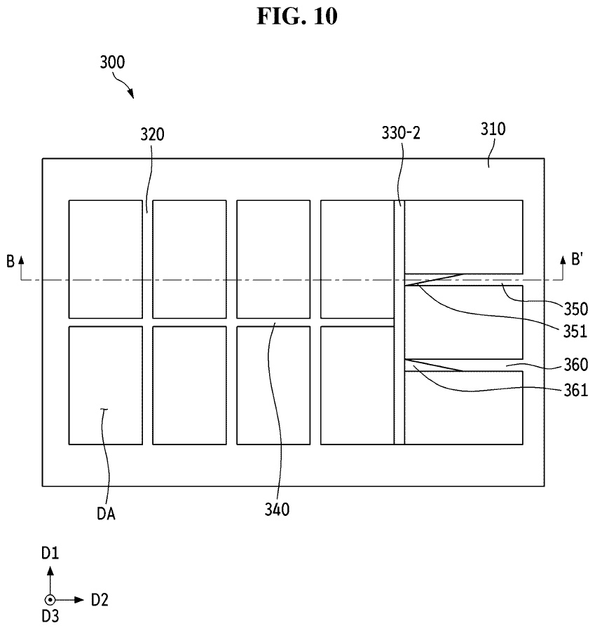

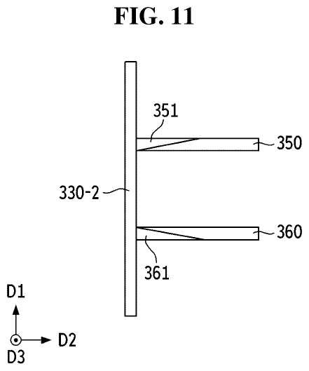

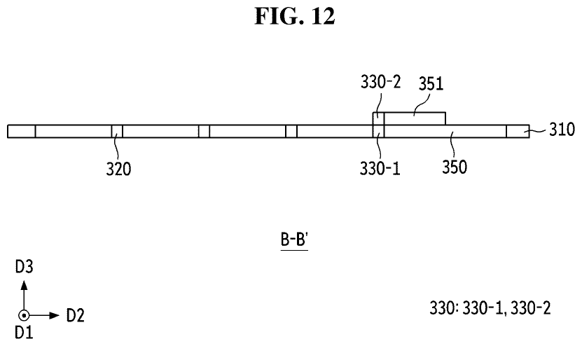

FIG. 10 is a plan view illustrating a second embodiment of a mask member in a mask assembly according to one embodiment of the present disclosure. FIG. 11 is a plan view illustrating a second main supporting part, a main reinforcing part, a first auxiliary supporting part, a first auxiliary reinforcing part, a second auxiliary supporting part, and a second auxiliary reinforcing part of FIG. 10. FIG. 12 is a cross-sectional view taken along line B-B′ of FIG. 10.

Referring to FIGS. 10 to 12, the mask member 300 according to the second embodiment may be disposed on the frame 100 and cover at least a portion of the first pattern openings 213 and the second pattern openings 223 to form a deposition area DA. The deposition area DA may correspond to one display device (e.g., organic display device). In this case, patterns corresponding to a plurality of display devices may be simultaneously deposited through a single process using one mask assembly 10. In some embodiments, the mask assembly 10 may correspond to one raw substrate (mother substrate), and may simultaneously form patterns corresponding to the plurality of display devices on the raw substrate.

The mask member 300 may include an edge part 310, a first main supporting part 320, a second main supporting part 330, 330-2a third main supporting part 340, a first auxiliary supporting part 350, a first auxiliary reinforcing part 351, a second auxiliary supporting part 360, and a second auxiliary reinforcing part 361. The second main supporting part 330 may include a first part 330-1 and a second part 330-2 (hereinafter, “main reinforcing part”).

The edge part 310 forms an outer frame of the mask member 300, and may have a square strip shape with a mask opening defined in the center therein. The edge part 310 may include a pair of short sides and a pair of long sides, and the mask opening may be defined in the center therein. For example, the one pair of short sides may be extended in the first direction D1 to be disposed parallel in the second direction D2, and the one pair of long sides may be extended in the second direction D2 to be disposed parallel in the first direction D1. The length of the short side of the edge part 310 may be shorter than the length of the short side of the frame 100, and the length of the long side of the edge part 310 may be shorter than the length of the short side of the frame 100.

In one embodiment, the planar shape of the mask opening may be approximately rectangular. The mask opening may provide a path through which a deposition material passes. The mask opening may be divided by a plurality of supporting parts to form the deposition area DA.

The first main supporting part 320 may extend from the edge part 310 in the first direction D1 to cross the mask opening. In some embodiments, the first main supporting part 320 may extend in the first direction D1 from the lower side of the edge part 310 of FIG. 10 to the upper side of the edge part 310 of FIG. 10. The first main supporting part 320 may be provided in plural numbers and be disposed to be spaced apart in the second direction D2. The thickness of the first main supporting part 320 may correspond to the thickness of the edge part 310.

The first part 330-1 may extend from the edge part 310 in the first direction D1 to cross the mask opening. In some embodiments, the first part 330-1 may extend in the first direction D1 from the lower side of the edge part 310 of FIG. 10 to the upper side of the edge part 310 of FIG. 10. The first part 330-1 may be disposed to be spaced apart from the first main supporting part 320 in the second direction D2.

The width of the first part 330-1 (width in the second direction D2) may be wider than each of the width of the first main supporting part 320 (width in the second direction D2) and the width of the third main supporting part 340 (width in the first direction D1). In addition, the width of the first part 330-1 may be wider than each of the width of the first auxiliary supporting part 350 (width in the first direction D1) and the width of the second auxiliary supporting part 360 (width in the first direction D1). In some embodiments, the width of the first part 330-1 may be formed to be wider than each of the width of the first main supporting part 320, the width of the third main supporting part 340, the width of the first auxiliary supporting part 350, and the width of the second auxiliary supporting part 360 to have an even greater rigidity. Accordingly, the second main supporting part 330 may be effectively prevented from being easily deformed.

The thickness of the first part 330-1 may correspond to each of the thickness of the edge part 310, the thickness of the first main supporting part 320, the thickness of the third main supporting part 340, the thickness of the first auxiliary supporting part 350, and the thickness of the second auxiliary supporting part 360.

The main reinforcing part 330-2 may be disposed on the first part 330-1. The main reinforcing part 330-2 may have a length corresponding to the length of the first part 330-1 in the first direction D1 and a width corresponding to the width of the first part 330-1 in the second direction D2. As the main reinforcing part 330-2 is disposed on the upper portion of the first part 330-1, the thickness of the first part 330-1 including the main reinforcing part 330-2 may become thicker than each of the thickness of the edge part 310, the thickness of the first main supporting part 320, the thickness of the third main supporting part 340, the thickness of the first auxiliary supporting part 350, and the second auxiliary supporting part 360. The main reinforcing part 330-2 may be provided separately from the first part 330-1 to be disposed on the top portion of the first part 330-1, or may be integrally formed with the first part 330-1.

The third main supporting part 340 may be extended from the edge part 310 to cross the mask opening in the second direction D2. In some embodiments, the third main supporting part 340 may be extended from the left side of FIG. 10 of the edge part 310 in the second direction D2 to be connected to a plurality of first main supporting parts 320 and the first part 330-1. Like described above, as the third main supporting part 340 is connected to the plurality of first main supporting parts 320 and second main supporting parts 330, a deposition area DA may be formed between the third main supporting part 340 and the plurality of first main supporting parts 320 and the first part 330-1. The thickness of the third main supporting part 340 may correspond to the thickness of the edge part 310.

The first auxiliary supporting part 350 may be extended from the first part 330-1 to cross the mask opening in the second direction D2. In some embodiments, the first auxiliary supporting part 350 may be extended from the first part 330-1 in the second direction D2 to be connected to the edge part 310. Like described above, as the first auxiliary supporting part 350 is connected to the first part 330-1 and the edge part 310, the deposition area DA may be formed between the first part 330-1, the first auxiliary supporting part 350, and the edge part 310. The thickness of the first auxiliary supporting part 350 may correspond to the thickness of the edge part 310. In addition, the thickness of the first auxiliary supporting part 350 may correspond to the thickness of the first part 330-1.

The first auxiliary reinforcing part 351 may be disposed on the first auxiliary supporting part 350. The first auxiliary reinforcing part 351 may extend from the main reinforcing part 330-2 in the second direction D2, but the cross-sectional area in the first direction D1 may gradually decrease nearing toward the second direction D2. In some embodiments, the width of the first auxiliary reinforcing part 351 in the first direction D1 may gradually decrease nearing toward the second direction D2.

When the first auxiliary reinforcing part 351 is viewed from a plan view, the first auxiliary reinforcing part 351 may include a first inclined surface extending in the second direction D2. The first inclined surface may be extended from the main reinforcing part 330-2 to be inclined toward the edge part 310 adjacent to the first auxiliary supporting part 350. In some embodiments, the first inclined surface may be extended in the second direction D2 from the main reinforcing part 330-2, but may be extended to be inclined in the upper direction of FIG. 10. As the first auxiliary reinforcing part 351 is disposed on the upper portion of the first auxiliary supporting part 350, the total thickness of the first auxiliary supporting part 350 and the first auxiliary reinforcing part 351 may be increased. As the total thickness of the first auxiliary supporting part 350 and the first auxiliary reinforcing part 351 increases and the first auxiliary reinforcing part 351 is formed to be inclined toward the upper direction of FIG. 10, the sum of the first auxiliary supporting part 350 and the first auxiliary reinforcing part 351 may have an even greater rigidity, and accordingly, may prevent the first auxiliary supporting part 350 from being bent in the upper direction of FIG. 10. The first auxiliary reinforcing part 351 may be provided separately from the first auxiliary supporting part 350 and be disposed on the upper portion of the first auxiliary supporting part 350, or may be formed integrally with the first auxiliary supporting part 350. Additionally, the first auxiliary reinforcing part 351 may be formed integrally with the main reinforcing part 330-2.

The second auxiliary supporting part 360 may be extended from the first part 330-1 to cross the mask opening in the second direction D2. In some embodiments, the second auxiliary supporting part 360 may be extended from the first part 330-1 in the second direction D2 to be connected to the edge part 310. The second auxiliary supporting part 360 may be disposed to be spaced apart from the first auxiliary supporting part 350 in the first direction D1. Like described above, as the second auxiliary supporting part 360 is connected to the first part 330-1 and the edge part 310, the deposition area DA may be formed between the first part 330-1, the first auxiliary supporting part 350, the second auxiliary supporting part 360, and the edge part 310. The thickness of the second auxiliary supporting part 360 may correspond to the thickness of the edge part 310. Additionally, the thickness of the second auxiliary supporting part 360 may be the same or less than the thickness of the first part 330-1.

The second auxiliary reinforcing part 361 may be disposed on the second auxiliary supporting part 360. The second auxiliary reinforcing part 361 may be extended in the second direction D2 from the main reinforcing part 330-2, but the cross-sectional area in the first direction D1 may gradually decrease nearing toward the second direction D2. In some embodiments, the width of the second auxiliary reinforcing part 361 may gradually decrease nearing toward the second direction D2.

When the second auxiliary reinforcing part 361 is viewed from a plan view, the second auxiliary reinforcing part 361 may include a second inclined surface extending in the second direction D2. The second inclined surface may be extended from the main reinforcing part 330-2 to be inclined toward the edge part 310 adjacent to the second auxiliary supporting part 360. In some embodiments, the second inclined surface may be extended from the main reinforcing part 330-2 in the second direction D2, but may be extended to be inclined in the lower direction of FIG. 10. As the second auxiliary reinforcing part 361 is disposed on the upper portion of the second auxiliary supporting part 360, the thickness of the second auxiliary supporting part 360 may be increased. As the thickness of the second auxiliary supporting part 360 increases and the second auxiliary reinforcing part 361 is formed to be inclined toward the lower direction of FIG. 10, the second auxiliary supporting part 360 may have an even greater rigidity, and accordingly, may prevent the second auxiliary supporting part 360 from being bent in the lower direction of FIG. 10. The second auxiliary reinforcing part 361 may be provided separately from the second auxiliary supporting part 360 and be disposed on the upper portion of the second auxiliary supporting part 360, or may be formed integrally with the second auxiliary supporting part 360. Additionally, the second auxiliary reinforcing part 361 may be formed integrally with the main reinforcing part 330-2.

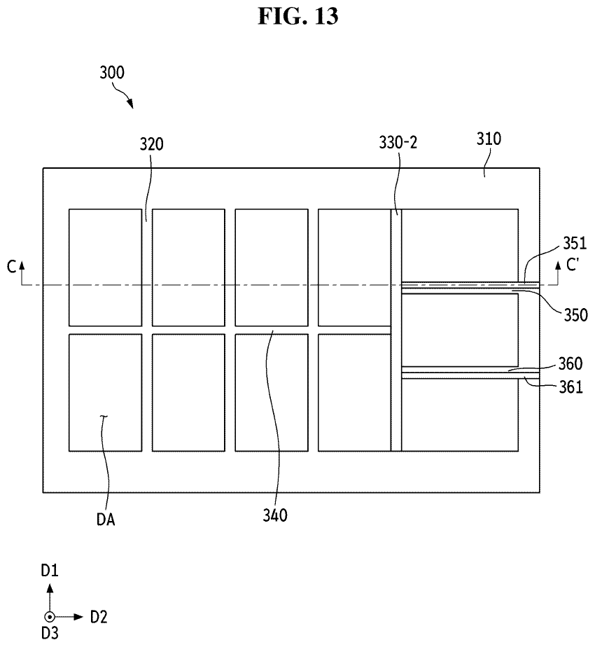

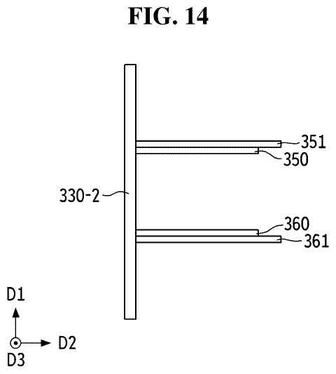

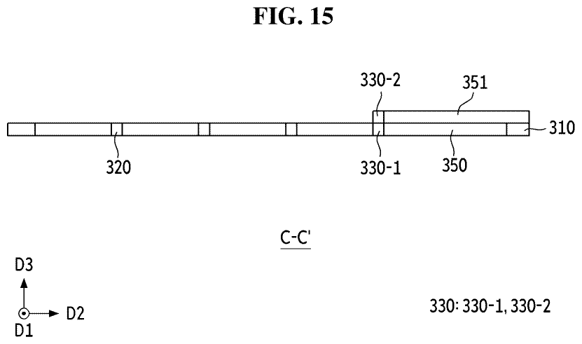

FIG. 13 is a plan view illustrating a third embodiment of a mask member in a mask assembly according to one embodiment of the present disclosure. FIG. 14 is a plan view illustrating a second main supporting part, a main reinforcing part, a first auxiliary supporting part, a first auxiliary reinforcing part, a second auxiliary supporting part, and a second auxiliary reinforcing part of FIG. 13. FIG. 15 is a cross-sectional view taken along line C-C′ of FIG. 13.

Referring to FIGS. 13 to 15, the mask member 300 according to the third embodiment may be disposed on the frame 100 and cover at least a portion of the first pattern openings 213 and the second pattern openings 223 to form a deposition area DA. The deposition area DA may correspond to one display device (e.g., an organic light emitting display device). In this case, patterns corresponding to a plurality of display devices may be simultaneously deposited by a single process using one mask assembly 10. In some embodiments, the mask assembly 10 may correspond to one raw substrate (a mother substrate) and may form patterns corresponding to a plurality of display devices on the raw substrate.

The mask member 300 may include an edge part 310, a first main supporting part 320, a second main supporting part 330, 330-2a third main supporting part 340, a first auxiliary supporting part 350, a first auxiliary reinforcing part 351, a second auxiliary supporting part 360, and a second auxiliary reinforcing part 361. The second main supporting part 330 may include a first part 330-1 and a second part 330-2 (hereinafter, “main reinforcing part”).

The edge part 310 forms an outer frame of the mask member 300, and may have a square strip shape with a mask opening defined in the center therein. The edge part 310 may include a pair of short sides and a pair of long sides, and the mask opening may be defined in the center therein. For example, the one pair of short sides may be extended in the first direction D1 to be disposed parallel in the second direction D2, and the one pair of long sides may be extended in the second direction D2 to be disposed parallel in the first direction D1. The length of the short side of the edge part 310 may be shorter than the length of the short side of the frame 100, and the length of the long side of the edge part 310 may be shorter than the length of the short side of the frame 100.

In one embodiment, the planar shape of the mask opening may be approximately rectangular. The mask opening may provide a path through which a deposition material passes. The mask opening may be divided by a plurality of supporting parts to form the deposition area DA.

The first main supporting part 320 may extend from the edge part 310 in the first direction D1 to cross the mask opening. In some embodiments, the first main supporting part 320 may extend in the first direction D1 from the lower side of the edge part 310 of FIG. 13 to the upper side of the edge part 310 of FIG. 13. The first main supporting part 320 may be provided in plural numbers and be disposed to be spaced apart in the second direction D2. The thickness of the first main supporting part 320 may correspond to the thickness of the edge part 310.

The first part 330-1 may extend from the edge part 310 in the first direction D1 to cross the mask opening. In some embodiments, the first part 330-1 may extend in the first direction D1 from the lower side of the edge part 310 of FIG. 13 to the upper side of the edge part 310 of FIG. 13. The first part 330-1 may be disposed to be spaced apart from the first main supporting part 320 in the second direction D2.

The width of the first part 330-1 (width in the second direction D2) may be wider than each of the width of the first main supporting part 320 (width in the second direction D2) and the width of the third main supporting part 340 (width in the first direction D1). In addition, the width of the first part 330-1 may be wider than each of the width of the first auxiliary supporting part 350 (width in the first direction D1) and the width of the second auxiliary supporting part 360 (width in the first direction D1). In some embodiments, the width of the first part 330-1 may be formed to be wider than each of the width of the first main supporting part 320, the width of the third main supporting part 340, the width of the first auxiliary supporting part 350, and the width of the second auxiliary supporting part 360 to have an even greater rigidity. Accordingly, the second main supporting part 330 may be prevented from being easily deformed.

The thickness of the first part 330-1 may correspond to each of the thickness of the edge part 310, the thickness of the first main supporting part 320, the thickness of the third main supporting part 340, the thickness of the first auxiliary supporting part 350, and the thickness of the second auxiliary supporting part 360.

The main reinforcing part 330-2 may be disposed on the first part 330-1. The main reinforcing part 330-2 may have a length corresponding to the length of the first part 330-1 in the first direction D1 and a width corresponding to the width of the first part 330-1 in the second direction D2. As the main reinforcing part 330-2 is disposed on the upper portion of the first part 330-1, the thickness of the first part 330-1 including the main reinforcing part 330-2 may become thicker than each of the thickness of the edge part 310, the thickness of the first main supporting part 320, the thickness of the third main supporting part 340, the thickness of the first auxiliary supporting part 350, and the second auxiliary supporting part 360. The main reinforcing part 330-2 may be provided separately from the first part 330-1 to be disposed on the upper portion of the first part 330-1, or may be integrally formed with the first part 330-1.

The third main supporting part 340 may be extended from the edge part 310 to cross the mask opening in the second direction D2. In some embodiments, the third main supporting part 340 may be extended from the left side of FIG. 13 of the edge part 310 in the second direction D2 to be connected to a plurality of first main supporting parts 320 and the first part 330-1. Like described above, as the third main supporting part 340 is connected to the plurality of first main supporting parts 320 and second main supporting parts 330, deposition areas DA may be formed between the third main supporting part 340 and the plurality of first main supporting parts 320 and the first part 330-1. The thickness of the third main supporting part 340 may correspond to the thickness of the edge part 310.

The first auxiliary supporting part 350 may be extended from the first part 330-1 to cross the mask opening in the second direction D2. In some embodiments, the first auxiliary supporting part 350 may be extended from the first part 330-1 in the second direction D2 to be connected to the edge part 310 of the right side. Like described above, as the first auxiliary supporting part 350 is connected to the first part 330-1 and the edge part 310, deposition areas DA may be formed between the first part 330-1, the first auxiliary supporting part 350, and the edge part 310. The thickness of the first auxiliary supporting part 350 may correspond to the thickness of the edge part 310. In addition, the thickness of the first auxiliary supporting part 350 may correspond to the thickness of the first part 330-1.

The first auxiliary reinforcing part 351 may be disposed on the first auxiliary supporting part 350. The first auxiliary reinforcing part 351 may have a width smaller than the width of the first auxiliary supporting part 350 in the first direction D1 and a length longer than the length of the first auxiliary supporting part 350 in the second direction D2. In some embodiments, the first auxiliary reinforcing part 351 may be formed to have a width smaller than the width of the first auxiliary supporting part 350 in the first direction D1 and extend in the second direction D2 from the main reinforcing part 330-2 to the outer end of the edge part 310.

The first auxiliary reinforcing part 351 may be disposed on a side closer to the edge part 310 among both sides of the first auxiliary supporting part 350 in the second direction D2. In some embodiments, the first auxiliary reinforcing part 351 may be disposed in the second direction D2 on the side of the upper direction of FIG. 13 among both sides of the first auxiliary supporting part 350. As the first auxiliary reinforcing part 351 is disposed on the upper portion of the first auxiliary supporting part 350, the total thickness of the first auxiliary supporting part 350 and the first auxiliary reinforcing part 351 may be increased compared to a part of the first auxiliary supporting part 350 without the first auxiliary reinforcing part 351 thereon. As the total thickness of the first auxiliary supporting part 350 and the first auxiliary reinforcing part 351 increases and the first auxiliary reinforcing part 351 is disposed on the side of the upper direction of FIG. 13 of the first auxiliary supporting part 350, the first auxiliary supporting part 350 may have even greater rigidity, and accordingly, may prevent the first auxiliary supporting part 350 from being bent in the upper direction of FIG. 13. The first auxiliary reinforcing part 351 may be provided separately from the first auxiliary supporting part 350 and be disposed on the upper portion of the first auxiliary supporting part 350, or may be formed integrally with the first auxiliary supporting part 350. Additionally, the first auxiliary reinforcing part 351 may be formed integrally with the main reinforcing part 330-2.

The second auxiliary supporting part 360 may be extended from the first part 330-1 to cross the mask opening in the second direction D2. In some embodiments, the second auxiliary supporting part 360 may be extended from the first part 330-1 in the second direction D2 to be connected to the edge part 310. The second auxiliary supporting part 360 may be disposed to be spaced apart from the first auxiliary supporting part 350 in the first direction D1. Like described above, as the second auxiliary supporting part 360 is connected to the first part 330-1 and the edge part 310, the deposition area DA may be formed between the first part 330-1, the first auxiliary supporting part 350, the second auxiliary supporting part 360, and the edge part 310. The thickness of the second auxiliary supporting part 360 may correspond to the thickness of the edge part 310. Additionally, the thickness of the second auxiliary supporting part 360 may be the same or less than the thickness of the first part 330-1.

The second auxiliary reinforcing part 361 may be disposed on the second auxiliary supporting part 360. The second auxiliary reinforcing part 361 may have a width smaller than the width of the second auxiliary supporting part 360 in the first direction D1 and a length longer than the length of the second auxiliary supporting part 360 in the second direction D2. In some embodiments, the second auxiliary reinforcing part 361 may be formed to have a width smaller than the width of the second auxiliary supporting part 360 and extend in the second direction D2 from the main reinforcing part 330-2 to the outer end of the edge part 310.

The second auxiliary reinforcing part 361 may be disposed on a side closer to the edge part 310 among both sides of the second auxiliary supporting part 360 in the second direction D2. In some embodiments, the second auxiliary reinforcing part 361 may be disposed in the second direction D2 on the side of the lower direction of FIG. 13 among both sides of the second auxiliary supporting part 360. As the second auxiliary reinforcing part 361 is disposed on the upper portion of the second auxiliary supporting part 360, the thickness of the second auxiliary supporting part 360 may be increased. As the thickness of the second auxiliary supporting part 360 increases and the second auxiliary reinforcing part 361 is disposed on the side of the lower direction of FIG. 13 of the second auxiliary supporting part 360, the second auxiliary supporting part 360 may have even greater rigidity, and accordingly, may prevent the second auxiliary supporting part 360 from being bent in the lower direction of FIG. 13. The second auxiliary reinforcing part 361 may be provided separately from the second auxiliary supporting part 360 and be disposed on the upper portion of the second auxiliary supporting part 360, or may be formed integrally with the second auxiliary supporting part 360. Additionally, the second auxiliary reinforcing part 361 may be formed integrally with the main reinforcing part 330-2.

The display device according to one embodiment of the present disclosure can be applied to various electronic devices. The electronic device according to the one embodiment of the present disclosure includes the display device described above, and may further include modules or devices having additional functions in addition to the display device.

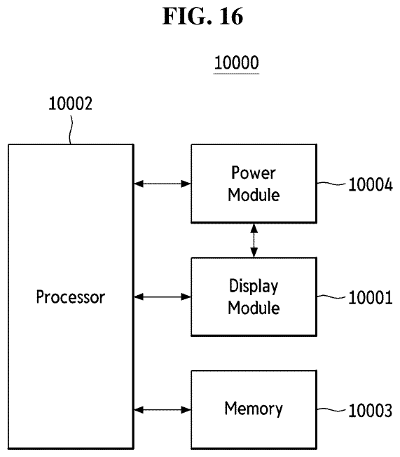

FIG. 16 is a block diagram of an electronic device according to one embodiment of the present disclosure.

Referring to FIG. 16, the electronic device 10000 according to one embodiment of the present disclosure may include a display module 10001, a processor 10002, a memory 10003, and a power module 10004.

The processor 10002 may include at least one of a central processing unit (CPU), an application processor (AP), a graphic processing unit (GPU), a communication processor (CP), an image signal processor (ISP), and a controller.

The memory 10003 may store data information necessary for the operation of the processor 10002 or the display module 10001. When the processor 10002 executes an application stored in the memory 10003, an image data signal and/or an input control signal is transmitted to the display module 10001, and the display module 10001 can process the received signal and output image information through a display screen.

The power module 10004 may include a power supply module such as, for example a power adapter or a battery, and a power conversion module that converts the power supplied by the power supply module to generate power necessary for the operation of the electronic device 10000.

At least one of the components of the electronic device 10000 according to the one embodiment of the present disclosure may be included in the display device according to the embodiments of the present disclosure. In addition, some modules of the individual modules functionally included in one module may be included in the display device, and other modules may be provided separately from the display device. For example, the display device may include the display module 10001, and the processor 10002, the memory 10003, and the power module 10004 may be provided in the form of other devices within the electronic device 10000 other than the display device.

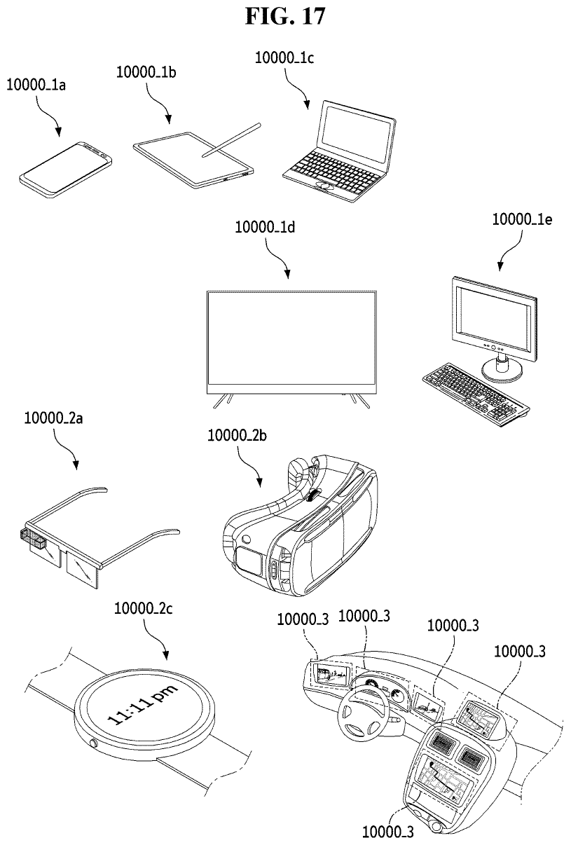

FIG. 17 is a schematic diagram of an electronic device according to various embodiments of the present disclosure.

Referring to FIG. 17, various electronic devices to which display devices according to embodiments of the present disclosure are applied may include not only image display electronic devices such as a smart phone 10000_1a, a tablet PC (personal computer) 10000_1b, a laptop 10000_1c, a TV 10000_1d, and a desk monitor 10000_1e, but also wearable electronic devices including display modules such as, for example smart glasses 10000_2a, a head mounted display 10000_2b, and a smart watch 10000_2c, and vehicle electronic devices 10000_3 including display modules such as a CID (Center Information Display) and a room mirror display arranged on a dashboard, center fascia, and dashboard of an automobile.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A mask assembly comprising:
a frame in which an opening is defined;
a mask stick disposed on the frame and in which a plurality of pattern openings are defined; and
a mask member disposed on the frame and including a plurality of supporting parts covering at least a portion of the pattern openings to form a deposition area,
wherein at least one supporting part among the plurality of supporting parts is wider in width or thicker in thickness than other supporting parts.

2. The mask assembly of claim 1,
wherein the mask member further comprises an edge part forming a mask opening therein, and
the plurality of supporting parts comprises:
a first main supporting part extending in a first direction from the edge part to cross the mask opening;
a second main supporting part extending in the first direction from the edge part to cross the mask opening and spaced apart from the first main supporting part; and
at least one auxiliary supporting part extending in a second direction crossing the first direction from the second main supporting part to the edge part.

3. The mask assembly of claim 2,
wherein a width of the second main supporting part in the second direction is wider than a width of each of the at least one the auxiliary supporting part in the first direction.

4. The mask assembly of claim 2,
wherein a width of the second main supporting part in the second direction is wider than a width of the first main supporting part in the second direction.

5. The mask assembly of claim 2,
wherein a thickness of the second main supporting part is thicker than a thickness of the auxiliary supporting part.

6. The mask assembly of claim 2,
wherein a thickness of the second main supporting part is thicker than a thickness of the first main supporting part.

7. The mask assembly of claim 2,
wherein the second main supporting part includes a first part and a main reinforcing part disposed on the first part,
wherein the plurality of supporting parts further comprises:
an auxiliary reinforcing part disposed on the auxiliary supporting part.

8. The mask assembly of claim 7,
wherein a total thickness of the auxiliary supporting part and the auxiliary reinforcing part is the same as a thickness of the second main supporting part.

9. The mask assembly of claim 7,
wherein the auxiliary reinforcing part extends from the main reinforcing part in the second direction.

10. The mask assembly of claim 9,
wherein a length of the auxiliary reinforcing part in the second direction is shorter than a length of the auxiliary supporting part in the second direction.

11. The mask assembly of claim 7,
wherein a width of the auxiliary reinforcing part in the first direction is the same as a width of the auxiliary supporting part in the first direction.

12. The mask assembly of claim 7,
wherein the auxiliary supporting part is provided in plural numbers,
the plurality of auxiliary supporting parts includes a first auxiliary supporting part and a second auxiliary supporting part,
the auxiliary reinforcing part is provided in plural numbers,
the plurality of auxiliary reinforcing parts includes a first auxiliary reinforcing part and a second auxiliary reinforcing part,
the first auxiliary reinforcing part is disposed on the first auxiliary supporting part, and
the second auxiliary reinforcing part is disposed on the second auxiliary supporting part.

13. The mask assembly of claim 12,
wherein each of the first auxiliary reinforcing part and the second auxiliary reinforcing part are extended from the main reinforcing part in the second direction, but the cross-sectional area of each of the first auxiliary reinforcing part and the second auxiliary reinforcing part in the first direction gradually decreases in the second direction.

14. The mask assembly of claim 13,
wherein the first auxiliary reinforcing part comprises a first inclined surface,
the first inclined surface is extended in a direction between the first direction and the second direction,
the second auxiliary reinforcing part comprises a second inclined surface, and
the second inclined surface is extended in a direction between the second direction and a direction opposite to the first direction.

15. The mask assembly of claim 12,
wherein the first auxiliary reinforcing part and the second auxiliary reinforcing part are extended from the main reinforcing part to an outer end of the edge part in the second direction.

16. The mask assembly of claim 15,
wherein a width of the first auxiliary reinforcing part in the first direction is smaller than a width of the first auxiliary supporting part in the first direction, and
a width of the second auxiliary reinforcing part in the first direction is smaller than a width of the second auxiliary supporting part in the first direction.

17. The mask assembly of claim 16,
wherein the first auxiliary reinforcing part is disposed at a side closer to the edge part among opposite sides of the first auxiliary supporting part in the second direction, and
the second auxiliary reinforcing part is disposed at a side closer to the edge part among opposite sides of the second auxiliary supporting part in the second direction.

18. The mask assembly of claim 2,
wherein the plurality of supporting parts further comprises a third main supporting part extended from the edge part in the second direction to be connected to the first main supporting part and the second main supporting part.

19. The mask assembly of claim 1,
wherein the mask stick is provided in plural numbers, and
the plurality of mask sticks are consecutively arranged on the frame to cover the opening of the frame,
wherein at least one mask stick among the plurality of mask sticks has a wider width than the other mask sticks in the second direction.

20. An electronic device comprising:
a display device manufactured by a mask assembly;
a mask assembly comprising:
a frame in which an opening is defined;
a mask stick disposed on the frame and in which a plurality of pattern openings are defined; and
a mask member disposed on the frame and including a plurality of supporting parts covering at least a portion of the pattern openings to form a deposition area,
wherein at least one supporting part among the plurality of supporting parts is wider in width or thicker in thickness than other supporting parts.
